(19) United States
(12) Patent Application Publication
(10) Pub. No.: US 2025/0133745 A1
(43) Pub. Date: Apr. 24, 2025

(54) NON-VOLATILE MEMORY CELL, METHOD OF FABRICATING NON-VOLATILE MEMORY CELL, AND MEMORY CELL ARRAY THEREOF

(71) Applicant: MACRONIX INTERNATIONAL CO., LTD., HSINCHU (TW)

(72) Inventors: Dai-Ying LEE, Hsinchu County (TW); Ming-Hsiu LEE, Hsinchu City (TW); Zefu ZHAO, Taipei City (TW); Chee-Wee LIU, Taipei City (TW)

(21) Appl. No.: 18/489,078

(22) Filed: Oct. 18, 2023

(51) Int. Cl. H10B 53/30; H01L 21/28; H01L 23/522; H01L 23/528; H01L 29/51; H01L 29/66; H01L 29/78; H10B 51/30

(52) U.S. Cl. CPC H10B 53/30; H01L 23/5226; H01L 23/5283; H10B 51/30; H10D 30/0415; H10D 30/701; H10D 64/033; H10D 64/689

(57) ABSTRACT

A non-volatile memory cell includes a capacitor which includes a top electrode, a bottom electrode, a ferroelectric layer disposed between the top electrode and the bottom electrode, and an amorphous layer disposed between the top electrode and the bottom electrode, wherein an atomic arrangement of the amorphous layer is different from an atomic arrangement of the top electrode and the bottom electrode. A method of fabricating a non-volatile memory cell and a memory cell array thereof are also disclosed.

### BACKGROUND

### Field of Invention

The present disclosure relates to a non-volatile memory cell, a method of fabricating a non-volatile memory cell, and a memory cell array thereof.

### Description of Related Art

Computer memories are generally categorized into non-volatile and volatile memories. Volatile memories such as DRAMs and SRAMs are usually much faster and more robust but they suffer from the ability to retain information when power is removed. On the other hand, non-volatile such as EEPROM and flash RAM are retain data when power is removed but they are usually slower and have a limited life span.

In the recent years, with the advance of the film formation technique, researches have been extensively made on nonvolatile semiconductor memories using ferroelectric thin films. The ferroelectric random access memory (FeRAM) uses ferroelectric capacitors as storage media. The capacitor can be polarized in either positive polarized state or negative polarized state, which represents the data stored therein.

### SUMMARY

An aspect of the present disclosure provides a non-volatile memory cell. The non-volatile memory cell includes a capacitor which includes a top electrode, a bottom electrode, a ferroelectric layer disposed between the top electrode and the bottom electrode, and an amorphous layer disposed between the top electrode and the bottom electrode, wherein an atomic arrangement of the amorphous layer is different from an atomic arrangement of the top electrode and the bottom electrode.

In some embodiments, the amorphous layer is formed by an atomic layer deposition process, and a thickness of the amorphous layer is in a range from 0.5 nm to 5 nm.

In some embodiments, a memory window of the non-volatile memory cell is greater than or equal to 0.2 V.

In some embodiments, the amorphous layer is disposed between the ferroelectric layer and the bottom electrode.

In some embodiments, the capacitor further includes an additional amorphous layer disposed between the ferroelectric layer and the top electrode.

In some embodiments, the amorphous layer is disposed between the ferroelectric layer and the top electrode.

In some embodiments, the non-volatile memory cell further includes a transistor, an interlayer dielectric layer disposed on the transistor, and a conductive via disposed in the interlayer dielectric layer to couple the transistor to the capacitor.

In some embodiments, the bottom electrode is protruded from the interlayer dielectric layer, and a bottom of the bottom electrode is surrounded by a dielectric layer.

In some embodiments, the amorphous layer, the ferroelectric layer, and the top electrode are disposed on sidewalls and a top surface of the bottom electrode.

In some embodiments, the bottom electrode comprises a plurality of protrusions, the amorphous layer, the ferroelectric layer, and the top electrode are disposed on sidewalls and top surfaces of the protrusions, and a space between the protrusions is filled by the top electrode.

In some embodiments, a material of the top electrode and the bottom electrode comprises TIN, Ti, W, or Si.

In some embodiments, a material of the amorphous layer comprises TIN, Ti, Si, or SiO₂.

Another aspect of the disclosure provides a method of fabricating a ferroelectric non-volatile memory cell. The method includes forming a bottom electrode by performing a first deposition process; forming an amorphous layer on the bottom electrode by performing a second deposition process that is different from the first deposition process such that an atomic arrangement of the amorphous layer is different from an atomic arrangement of the bottom electrode; forming a ferroelectric layer on the bottom electrode; and forming a top electrode on the amorphous layer and the ferroelectric layer.

In some embodiments, a memory window of the non-volatile memory cell is greater than or equal to 0.2 V.

In some embodiments, the second deposition process is an atomic layer deposition process, and a thickness of the amorphous layer is in a range from 0.5 nm to 5 nm.

In some embodiments, the first deposition process is performed such that atomic layers of the bottom electrode are crystallized, and the second deposition process is performed such that atomic layers of the amorphous layer are not substantially crystallized.

In some embodiments, the method further includes performing a planarization process to the bottom electrode before the forming the amorphous layer and the forming the ferroelectric layer.

Yet another aspect of the disclosure provides a memory cell array. The memory cell array includes a plurality of bit lines arranged in a first direction, a plurality of word lines arranged in a second direction, a plurality of select lines, and a plurality of memory cells. Each of the memory cells includes a transistor and a capacitor coupled to the transistor. The capacitors are coupled between the bit lines and the select lines, respectively. Each of the capacitors includes a top electrode, a bottom electrode, a ferroelectric layer disposed between the top electrode and the bottom electrode, and an amorphous layer disposed between the top electrode and the bottom electrode. An atomic arrangement of the amorphous layer is different from an atomic arrangement of the top electrode and the bottom electrode.

In some embodiments, the select lines are arranged in the first direction, and the select lines and the bit lines are alternately arranged.

In some embodiments, the select lines are arranged in the second direction, and the select lines and the word lines are alternately arranged.

According to some embodiments of the disclosure, a non-volatile memory cell includes a capacitor is provided. The capacitor includes a top electrode, a bottom electrode, a ferroelectric layer between the top electrode and the bottom electrode, and one or more amorphous layers between the top electrode and the bottom electrode. The atomic arrangement of the amorphous layer is different from the atomic arrangement of the top electrode and the bottom electrode. The remnant polarization (2Pᵣ) of the capacitor can be increased by inserting the amorphous layer between the top electrode and the bottom electrode, and a memory window of the non-volatile memory cell is increased accordingly.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1 is a transition diagram of the polarized state of a capacitor, according to some embodiments of the disclosure;

FIG. 2 to FIG. 4 are schematic cross-sectional views of a non-volatile memory cell according to different embodiments of the disclosure;

FIG. 5 to FIG. 9 are cross-sectional views of different steps of fabricating a non-volatile memory cell, according to some embodiments of the disclosure;

FIG. 10 is a diagram illustrating remnant polarization (2Pᵣ) values of different structures of capacitors;

FIG. 11 and FIG. 12 are cross-sectional views of a non-volatile memory cell according to different embodiments of the disclosure; and

FIG. 13 and FIG. 14 are diagrams of a memory cell array according to different embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

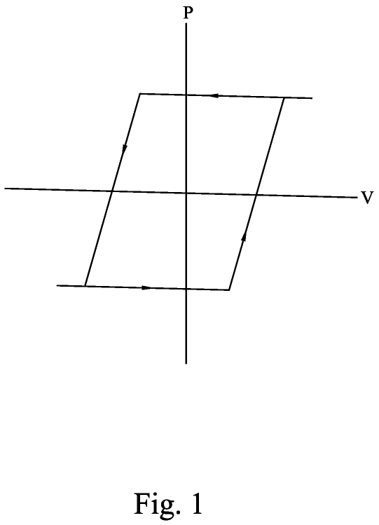

Ferroelectric random access memory (FeRAM) is a nonvolatile semiconductor memory which allows high speed rewriting by making use of high-speed polarization reversal and its residual polarization of a ferroelectric thin film. As shown in FIG. 1, FIG. 1 is a transition diagram of the polarized state of a capacitor, according to some embodiments of the disclosure. The capacitor can be a ferroelectric capacitor, and the ferroelectric materials of the capacitor exhibit a nonlinear relationship between the applied electric field (V) and the apparent stored charge (Q). Specifically, capacitors exhibit a characteristic hysteresis loop. The dielectric constant of a ferroelectric material is typically much higher than those of linear dielectrics because of the effects of semi-permanent electric dipoles formed in the crystal structure of the ferroelectric material. When an external electric field is applied across a ferroelectric material, the dipoles tend to align themselves with the field direction, producing shifts in the positions of atoms and corresponding shifts in the distribution of electronic charge within the unit cells of the ferroelectric material which represent the “up” and “down” states respectively. After the charge is removed, the dipoles retain their polarization state. Typically binary “0”s and “1”s are stored as one of two possible electric polarizations in each data storage cell. For example, with reference to FIG. 1, a “1” would typically be encoded using the negative remnant polarization “−Pᵣ”, and a “0” is encoded using the positive remnant polarization “+Pᵣ”.

The memory window is an important factor to the programming voltage of the FeRAM cell. The memory window is represented as (2Pᵣ×A)/C_{BL}. In which 2Pᵣ is remnant polarization, A is the area between top electrode and bottom electrode, and C_{BL} is capacitance to bit line. In order to increase the memory window of FeRAM cell, a large remnant polarization (2Pᵣ) is preferred in the present disclosure.

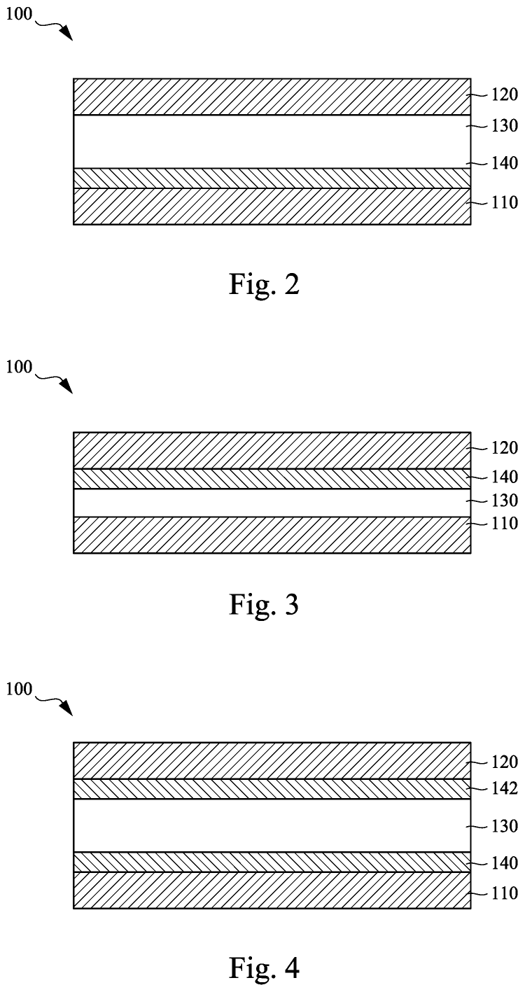

Reference is made to FIG. 2, which is a schematic cross-sectional view of a non-volatile memory cell according to some embodiments of the disclosure. The non-volatile memory cell such as a FeRAM structure includes a capacitor 100 such as a ferroelectric capacitor. The capacitor 100 includes a first electrode 110, a second electrode 120, a ferroelectric layer 130 between the first electrode 110 and the second electrode 120, and an amorphous layer 140 between the first electrode 110 and the second electrode 120. The atomic arrangement of the amorphous layer 140 is different from the atomic arrangement of the first electrode 110. The atomic arrangement of the amorphous layer 140 is different from the atomic arrangement of the second electrode 120.

The remnant polarization of the capacitor 100 can be increased by inserting the amorphous layer 140 between the first electrode 110 and the second electrode 120.

More particularly, the first electrode 110 and the second electrode 120 are formed by a first deposition process, and the amorphous layer 140 is formed by a second deposition process that is different from the first deposition process. For example, in some embodiments, the first electrode 110 and the second electrode 120 can be formed by a physical vapor deposition (PVD) process. The thickness of the first electrode 110 and the second electrode 120 is thick enough thereby presenting obvious crystallization of the atomic layers of the first electrode 110 and the second electrode 120. For example, the thickness of the first electrode 110 and the second electrode 120 is greater than 10 nm.

On the other hand, the amorphous layer 140 is formed by an atomic layer deposition (ALD) process such as a plasma enhanced atomic layer deposition (PEALD) process, therefore, the thickness of the amorphous layer 140 is really thin such as in a range from 0.5 nm to 5 nm, and the atomic layers of the amorphous layer 140 are not substantially crystallized. In some embodiments, if the thickness of the amorphous layer 140 is greater than 5 nm the atomic layers of the amorphous layer 140 may be crystallized, the function of increasing remnant polarization of the capacitor 100 is failed.

In some embodiments, the material of the first electrode 110 and the second electrode 120 can be TIN, Ti, W, Si, etc. In some embodiments, the material of the ferroelectric layer 130 can be HZO, HfO₂ based ferroelectric material, ZrO₂ based ferroelectric material, etc. In some embodiments, the material of the amorphous layer 140 can be TIN, Ti, Si, SiO₂, etc. In some embodiments, the first electrode 110, the second electrode 120, and the amorphous layer 140 respectively have different materials. In some embodiments, at least two the first electrode 110, the second electrode 120, and the amorphous layer 140 have the same materials with different atomic arrangements.

In some embodiments, the first electrode 110 serves as a bottom electrode of the capacitor 100, the second electrode 120 serves as a top electrode of the capacitor 100, and the amorphous layer 140 is disposed between the first electrode 110 and the ferroelectric layer 130.

In some other embodiments, as shown in FIG. 3, the first electrode 110 serves as a bottom electrode of the capacitor 100, the second electrode 120 serves as a top electrode of the capacitor 100, and the amorphous layer 140 is disposed between the second electrode 120 and the ferroelectric layer 130.

In some other embodiments, as shown in FIG. 4, the capacitor 100 further includes an additional amorphous layer 142. The amorphous layer 142 can be substantially identical to the amorphous layer 140 or have a different composition. The amorphous layer 140 is disposed between the first electrode 110 and the ferroelectric layer 130, and the additional amorphous layer 142 is disposed between the second electrode 120 and the ferroelectric layer 130.

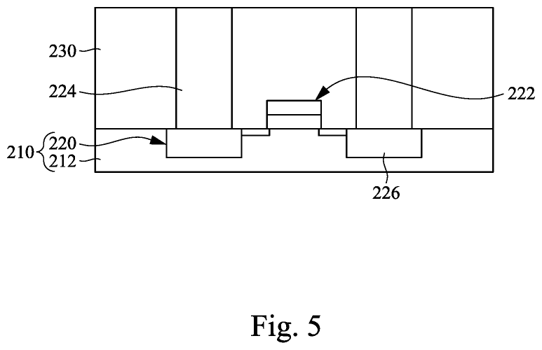

Reference is made to FIG. 5 to FIG. 9, in which FIG. 5 to FIG. 9 are cross-sectional views of different steps of a method of fabricating a non-volatile memory cell, according to some embodiments of the disclosure. The method starts from FIG. 5. A substrate 210 including a semiconductor substrate 212 and at least one device layer 220 formed on the semiconductor substrate 212 is provided. The device layer 220 has a plurality of integrated circuit (IC) devices including an active component such as a transistor 222, a switch, etc., and/or a passive component, such as a resistor, capacitor, inductor, transformer, etc. An interlayer dielectric layer 230 is then formed over the device layer 220, and a plurality of contact openings are formed in the interlayer dielectric layer 230 to expose portions of the source/drain 226 (sometimes abbreviated as S/D) regions of the transistor 222. The interlayer dielectric layer 230 may also be subjected to one or more planarization processes including chemical mechanical polishing (CMP) to provide a substantially planar surface suitable for additional processing. A plurality of conductive vias 224 are then formed through the contact openings to provide an electrical path to each of the S/D regions 226 of the transistor 222.

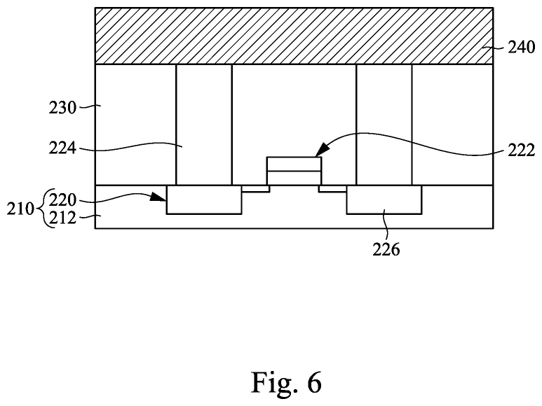

As shown in FIG. 6, a deposition process such as a physical vapor deposition process is performed to form a bottom electrode material layer 240 on the interlayer dielectric layer 230. In some embodiments, the material of the bottom electrode material layer 240 can be TIN, Ti, W, Si, etc., and the thickness of the bottom electrode material layer 240 is greater than 10 nm. The bottom electrode material layer 240 is formed to present obvious crystallization of the atomic layers of the bottom electrode material layer 240.

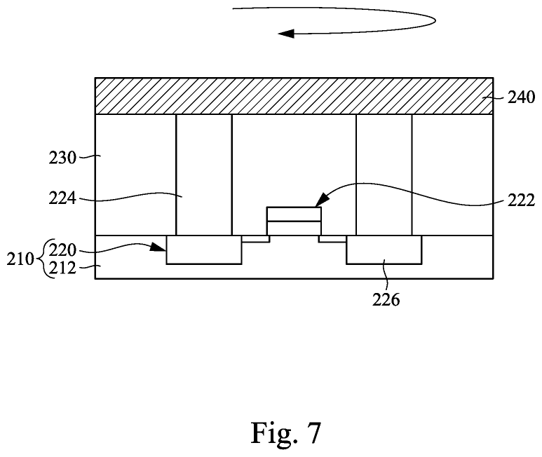

As shown in FIG. 7, a planarization process is optionally performed to the bottom electrode material layer 240 such that the roughness of the top surface of the bottom electrode material layer 240 is improved. For example, the surface roughness of the top surface of the bottom electrode material layer 240 is about 3 nm before the planarization process is performed, and the surface roughness of the top surface of the bottom electrode material layer 240 is about 0.5 nm after the planarization process is performed. The improved surface roughness of the top surface of the bottom electrode material layer 240 is benefit to the following deposition processes.

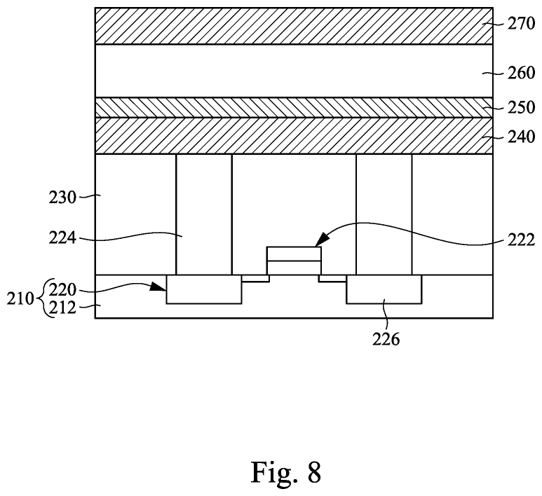

As shown in FIG. 8, a series of depositions processes are performed to form an amorphous material layer 250, a ferroelectric material layer 260, and a top electrode material layer 270 on the bottom electrode material layer 240. In some embodiments, the amorphous material layer 250 is deposited on the bottom electrode material layer 240, the ferroelectric material layer 260 is deposited on the amorphous material layer 250, and the top electrode material layer 270 is deposited on the ferroelectric material layer 260.

In some other embodiments, the ferroelectric material layer 260 is deposited on the bottom electrode material layer 240, the amorphous material layer 250 is deposited on the ferroelectric material layer 260, and the top electrode material layer 270 is deposited on the amorphous material layer 250. In yet some other embodiments, the series of deposition processes further include depositing an additional amorphous material layer (not shown) such that the amorphous material layers are respectively formed between the bottom electrode material layer 240 and the ferroelectric material layer 260 and between the ferroelectric material layer 260 and the top electrode material layer 270.

In some embodiments, the material of the amorphous material layer 250 can be TiN, Ti, Si, SiO₂, etc. The amorphous material layer 250 is formed by an ALD process such as a PEALD process, therefore, the thickness of the amorphous material layer 250 is in a range from 0.5 nm to 5 nm, and the atomic layers of amorphous material layer 250 are not substantially crystallized.

In some embodiments, the material of the ferroelectric material layer 260 can be HZO, HfO₂ based ferroelectric material, ZrO₂ based ferroelectric material, etc. The deposition process of forming the ferroelectric material layer 260 can be chemical vapor deposition process, and the thickness of the ferroelectric material layer 260 is in a range from 5 nm to 50 nm.

In some embodiments, the material of the top electrode material layer 270 can be TIN, Ti, W, Si, etc. The deposition process of forming the top electrode material layer 270 can be physical vapor deposition process, and the thickness of the top electrode material layer 270 is greater than 10 nm.

Due to the different deposition processes and thicknesses, the atomic arrangement of the amorphous material layer 250 is different from the atomic arrangement of the bottom electrode material layer 240 or the top electrode material layer 270. More particularly, the atomic arrangement of the amorphous material layer 250 is not substantially crystalized, and the atomic arrangement of the bottom electrode material layer 240 or the top electrode material layer 270 is substantially crystalized.

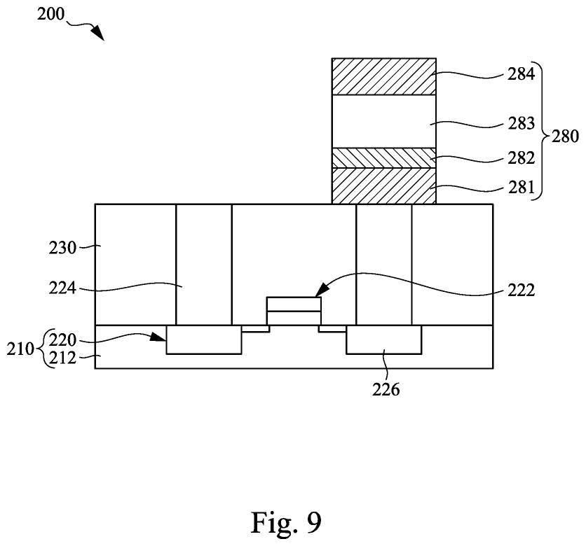

Finally, as shown in FIG. 9, a patterning process is performed to form a capacitor 280 on the interlayer dielectric layer 230 and is electrically coupled to the transistor 222 of the device layer 220 through the conductive via 224, in which the capacitor 280 includes a bottom electrode 281 in contact with the conductive via 224, a top electrode 284, a ferroelectric layer 283 between the bottom electrode 281 and the top electrode 284, and one or more amorphous layers 282 between the bottom electrode 281 and the top electrode 284. As such, a common configuration for the memory cell consists of a single capacitor and an associated transistor is formed, that can be referred to as a “1T-1C” or “1TC” memory cell of the non-volatile memory cell 200.

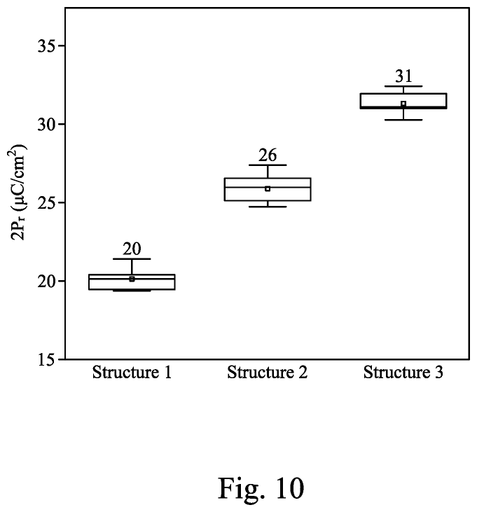

Reference is made to FIG. 10, which is a diagram illustrating remnant polarization (2Pᵣ) values of different structures of capacitors. The structure 1 is a conventional capacitor including a bottom electrode, a top electrode, and a ferroelectric layer between the top and bottom electrodes. The top and bottom electrodes of the capacitor of structure 1 are TiN, and the ferroelectric layers of the capacitor of structure 1 are HZO.

The structure 2 is an advanced capacitor including a bottom electrode, a top electrode, and a ferroelectric layer between the top and bottom electrodes, in which the bottom electrode is planarized by a CMP process. The top and bottom electrodes of the capacitor of structure 2 are TiN, and the ferroelectric layers of the capacitor of structure 2 are HZO.

The structure 3 is an embodiment of the capacitor of the present disclosure which includes a bottom electrode, a top electrode, and a ferroelectric layer between the top and bottom electrodes, and an amorphous layer between the ferroelectric layer and the bottom electrode, in which the bottom electrode is also planarized by a CMP process. The top and bottom electrodes of the capacitor of structure 3 are TiN, and the ferroelectric layers of the capacitor of structure 3 are HZO. The amorphous layer of the capacitor of structure 3 is a TiN formed by a PEALD process, and the thickness thereof is about 5 Å.

According to the test result, in which the remnant polarization values are average value of 10 dies, the remnant polarization value of the capacitor of structure 1 is about 20 μC/cm², the remnant polarization value of the capacitor of structure 2 is about 26 μC/cm², and the remnant polarization value of the capacitor of structure 3 is about 31 μC/cm².

In the non-volatile memory cell of the present disclosure, one or more amorphous layers are inserted between the top electrode and the bottom electrode of the capacitor to increasing the remnant polarization value of the capacitor such that the memory window of the non-volatile memory cell is greater than or equal to 0.2V, which is benefit to the programming voltage of the non-volatile memory cell.

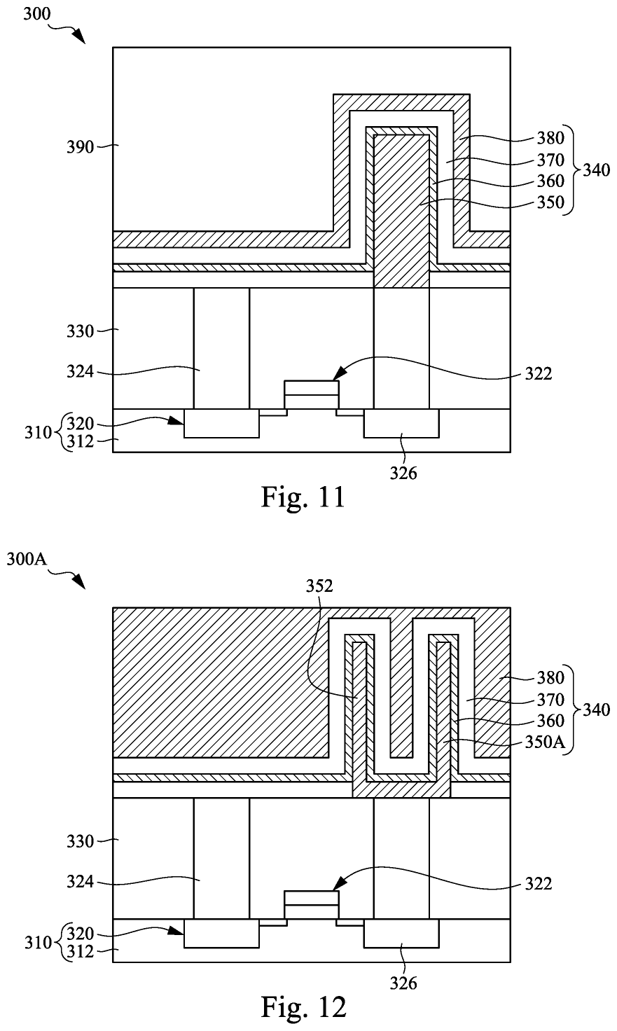

Reference is made to FIG. 11. FIG. 11 is a cross-sectional view of a non-volatile memory cell according to some embodiments of the disclosure. The non-volatile memory cell 300 includes substrate 310 having a semiconductor substrate 312 and at least one device layer 320 formed on the semiconductor substrate 312. The device layer 320 includes a transistor 322. An interlayer dielectric layer 330 is formed over the device layer 320, and a plurality of conductive vias 324 are formed in interlayer dielectric layer 330 to provide an electrical path to the S/D regions 326 of the transistor 322.

The non-volatile memory cell 300 further includes a capacitor 340 disposed on the interlayer dielectric layer 330 and electrically coupling to the S/D region 326 of the transistor 322 through the conductive via 324. In some embodiments, the capacitor 340 includes a bottom electrode 350 connected to the conductive via 324. The bottom electrode 350 is a conductive piece and is protruded from the interlayer dielectric layer 330. The capacitor 340 further includes one or more amorphous layers 360, a ferroelectric layer 370, and a top electrode 380. Example of the laminations of the one or more amorphous layers 360 and the ferroelectric layer 370 between the bottom electrode 350 and the top electrode 380 can be referred to FIG. 2 to FIG. 4.

In some embodiments, the amorphous layer 360 is disposed on and in contact with sidewalls and a top surface of the bottom electrode 350. The amorphous layer 360 is further extended above the transistor 322. A dielectric layer 332 is interposed between the amorphous layer 360 and interlayer dielectric layer 330, and a bottom of the bottom electrode 350 is surrounded by the dielectric layer 332. The ferroelectric layer 370 is disposed on the amorphous layer 360, and the top electrode 380 is disposed on ferroelectric layer 370. More particularly, the amorphous layer 360, the ferroelectric layer 370, and the top electrode 380 are formed lining the top surface and sidewalls of the bottom electrode 350 and the top surface of the dielectric layer 332. The non-volatile memory cell 300 further includes an additional interlayer dielectric layer 390 formed on the capacitor 340 to seal the capacitor 340.

The area between the bottom electrode 350 and top electrode 380 includes the area of the top surface of the bottom electrode 350 and the area of the sidewalls of the bottom electrode 350. Comparing to the embodiments as disclosed in FIG. 10, the area between the bottom electrode 350 and top electrode 380 is greatly increased thereby further enlarging the memory window of the of the non-volatile memory cell 300 of FIG. 11.

Reference is made to FIG. 12. FIG. 12 is a cross-sectional view of a non-volatile memory cell according to some other embodiments of the disclosure. One of the main differences between the non-volatile memory cell 300 of FIG. 11 and the non-volatile memory cell 300A of FIG. 12 is that the bottom electrode 350A of non-volatile memory cell 300A is further patterned to further increasing the surface area of the bottom electrode 350A thereby increasing the area between the bottom electrode 350A and top electrode 380 to further enlarge the memory window of the of the non-volatile memory cell 300A.

For example, the bottom electrode 350A is patterned as a comb having a plurality of protrusions 352, the amorphous layer 360 and the ferroelectric layer 370 are disposed lining the sidewalls and the top surfaces of the protrusions 352 of the bottom electrode 350A, and top electrode 380 is formed on the amorphous layer 360 and the ferroelectric layer 370. In some embodiments, the top electrode 380 is deposited thicker such that the top electrode 380 fills the space(s) between the protrusions 352 of the bottom electrode 350A.

In some other embodiments, the top electrode 380 is also formed lining the sidewalls and the top surface of the bottom electrode 350A, and the space(s) between the protrusions 352 of the bottom electrode 350A is filled by an additional dielectric layer such that the top electrode 380 on different protrusions 352 would not be merged.

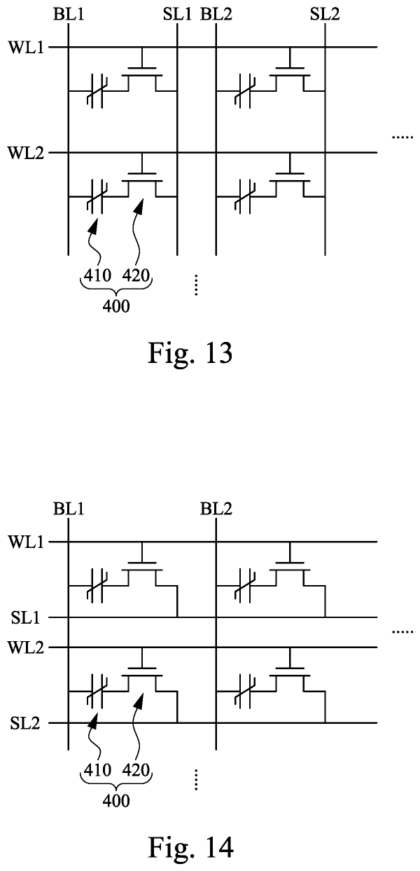

Reference is made to FIG. 13 and FIG. 14. FIG. 13 and FIG. 14 are diagrams of a memory cell array according to different embodiments of the disclosure. The memory cell is of a 1T1C type, which means the memory cell 400 includes a capacitor 410 and a transistor 420 coupled to the capacitor 410. The capacitor 410 includes one or more amorphous layers and a ferroelectric layer disposed between a top electrode and a bottom electrode. Examples of the laminations of the capacitor 410 can be referred to FIG. 2 to FIG. 4. Additionally, the structure design of the capacitor 410 on the transistor 420 can be referred to FIG. 9, FIG. 11, and FIG. 12.

The capacitor 410 is coupled between the bit line BL and the select line SL. The voltage of the capacitor 410 is the voltage difference between the select line SL and the bit line BL when the word line WL is enabled. The bit lines BLs such as BL1, BL2, . . . are arranged in a first direction such as X-direction, and the word lines WLs such as WL1, WL2, . . . are arranged in a second direction such as Y-direction that is perpendicular to the first direction.

In some embodiments, as illustrated in FIG. 13, the select lines SLs such as SL1, SL2, . . . are also arranged in the first direction such as X-direction, and the select lines SLs and the bit lines BLs are alternately arranged. Namely, each of the select lines SLs is disposed between the adjacent pair of the bit lines BLs.

In some other embodiments, as illustrated in FIG. 14, the select lines SLs are also arranged in the second direction such as Y-direction, and the select lines SLs and the word lines WLs are alternately arranged. Namely, each of the select lines SLs is disposed between the adjacent pair of the word lines WLs.

According to some embodiments of the disclosure, a non-volatile memory cell includes a capacitor is provided. The capacitor includes a top electrode, a bottom electrode, a ferroelectric layer between the top electrode and the bottom electrode, and one or more amorphous layers between the top electrode and the bottom electrode. The atomic arrangement of the amorphous layer is different from the atomic arrangement of the top electrode and the bottom electrode. The remnant polarization (2Pᵣ) of the capacitor can be increased by inserting the amorphous layer between the top electrode and the bottom electrode. The memory window of the non-volatile memory cell is increased accordingly.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims and their equivalents.

What is claimed is:

1. A non-volatile memory cell comprising:
a capacitor comprising:
a top electrode;
a bottom electrode;
a ferroelectric layer disposed between the top electrode and the bottom electrode; and
an amorphous layer disposed between the top electrode and the bottom electrode, wherein an atomic arrangement of the amorphous layer is different from an atomic arrangement of the top electrode and the bottom electrode.

2. The non-volatile memory cell of claim 1, wherein the amorphous layer is formed by an atomic layer deposition process, and a thickness of the amorphous layer is in a range from 0.5 nm to 5 nm.

3. The non-volatile memory cell of claim 1, wherein a memory window of the non-volatile memory cell is greater than or equal to 0.2V.

4. The non-volatile memory cell of claim 1, wherein the amorphous layer is disposed between the ferroelectric layer and the bottom electrode.

5. The non-volatile memory cell of claim 4, wherein the capacitor further comprising an additional amorphous layer disposed between the ferroelectric layer and the top electrode.

6. The non-volatile memory cell of claim 1, wherein the amorphous layer is disposed between the ferroelectric layer and the top electrode.

7. The non-volatile memory cell of claim 1, further comprising:
a transistor;
an interlayer dielectric layer disposed on the transistor; and
a conductive via disposed in the interlayer dielectric layer to couple the transistor to the capacitor.

8. The non-volatile memory cell of claim 7, wherein the bottom electrode is protruded from the interlayer dielectric layer, and a bottom of the bottom electrode is surrounded by a dielectric layer.

9. The non-volatile memory cell of claim 8, wherein the amorphous layer, the ferroelectric layer, and the top electrode are disposed on sidewalls and a top surface of the bottom electrode.

10. The non-volatile memory cell of claim 8, wherein the bottom electrode comprises a plurality of protrusions, the amorphous layer, the ferroelectric layer, and the top electrode are disposed on sidewalls and top surfaces of the protrusions, and a space between the protrusions is filled by the top electrode.

11. The non-volatile memory cell of claim 1, wherein a material of the top electrode and the bottom electrode comprises TIN, Ti, W, or Si.

12. The non-volatile memory cell of claim 1, wherein a material of the amorphous layer comprises TIN, Ti, Si, or SiO₂.

13. A method of fabricating a non-volatile memory cell, the method comprising:
forming a bottom electrode by performing a first deposition process;
forming an amorphous layer on the bottom electrode by performing a second deposition process that is different from the first deposition process such that an atomic arrangement of the amorphous layer is different from an atomic arrangement of the bottom electrode;
forming a ferroelectric layer on the bottom electrode; and
forming a top electrode on the amorphous layer and the ferroelectric layer.

14. The method of claim 13, wherein a memory window of the non-volatile memory cell is greater than or equal to 0.2V.

15. The method of claim 13, wherein the second deposition process is an atomic layer deposition process, and a thickness of the amorphous layer is in a range from 0.5 nm to 5 nm.

16. The method of claim 13, wherein the first deposition process is performed such that atomic layers of the bottom electrode are crystallized, and the second deposition process is performed such that atomic layers of the amorphous layer are not substantially crystallized.

17. The method of claim 13, further comprising performing a planarization process to the bottom electrode before the forming the amorphous layer and the forming the ferroelectric layer.

18. A memory cell array comprising;
a plurality of bit lines arranged in a first direction;
a plurality of word lines arranged in a second direction;
a plurality of select lines; and
a plurality of memory cells, each of the memory cells comprises a transistor and a capacitor coupled to the transistor, the capacitors coupled between the bit lines and the select lines, respectively, each of the capacitors comprising a top electrode, a bottom electrode, a ferroelectric layer disposed between the top electrode and the bottom electrode, and an amorphous layer disposed between the top electrode and the bottom electrode, wherein an atomic arrangement of the amorphous layer is different from an atomic arrangement of the top electrode and the bottom electrode.

19. The memory cell array of claim 18, wherein the select lines are arranged in the first direction, and the select lines and the bit lines are alternately arranged.

20. The memory cell array of claim 18, wherein the select lines are arranged in the second direction, and the select lines and the word lines are alternately arranged.
